(19) United States
(12) Patent Application Publication
(10) Pub. No.: US 2003/0183746 A1
(43) Pub. Date: Oct. 2, 2003

(54) High speed single-linear three-color CIS image sensing array

(76) Inventor: Pao-Jung Chen, Capertino, CA (US)

Correspondence Address: Pao-Jung Chen, 20872 Sola Street, Cupertino, CA, 95014, US

(21) Appl. No.: 10/115,297

(22) Filed: Apr. 2, 2002

(51) Int. Cl. H01L 27/00

(52) U.S. Cl. 250/208.1

(57) ABSTRACT

A single-linear color CIS image sensor chip built on silicon substrate is disclosed in this invention. This color image-sensing chip is realized by coating the RGB filters sequentially, in the order of RGBRGB . . . on each photo-detecting element of the sensor chip. A CIS scanner module incorporates these sensor chips as the image sensing array, and a fluorescent lamp as the light source will perform high speed, high quality color image scanning.

### TECHNICAL FIELD OF THE INVENTION

This invention relates to a color image-sensing array utilized to produce electronic images of documents and objects. Particular applications for these image-sensing arrays include contact image scanners used in document scanners, photocopiers and facsimile machines, and video cameras.

### BACKGROUND OF INVENTION

The contact image sensor (CIS) scanner is widely used in the markets of facsimile machines, multi-function devices, and PC scanners for the advantage of its compactness in size. This is due to the unique short optical path design of the CIS scanner module. The description of a CIS module was presented in a paper by E. E. Anderson and Weng-Lyang Wang entitled “A Novel Contact Image Sensor (CIS) module for Compact and Lightweight Full Page Scanner Applications,” SPIE Vol. 1901 Cameras, Scanners, and Image Acquisition Systems (1993), pages 173-181.

In the existing color CIS scanner market, there are two different types of module designs. One type of color CIS module uses the fluorescent lamp as the light source, and the tri-linear color image-sensing array as the sensor array. A color CIS module using color phototransistors was presented in a paper by Tadahiko Hamaguchi, et. al., entitled “Contact-type Color Image Sensor Using Color Phototransistors,” SPIE Vol. 2172, pages 167-174. As illustrated in FIGS. 1, 2 and 3, the tri-linear image-sensing array used in this module includes three parallel closely aligned linear photo-sensing arrays, wherein each array is coated with its respective color filter, red, green and blue, on its photo-detecting elements. There are three output channels on the sensor array chip. Each output channel corresponds to a respective color. During each line step of the scan, the fluorescent lamp projects three lines of image to the three photo-sensing arrays. The outputs of this information, together with information from the previous and the next step scan, are processed to produce the exact color image of that particular line. This CIS scanner module operates similarly to CCD scanners with tri-linear color CCD sensor chips which can be seen in the data sheet of ILX718K CCD sensor, Sony Corp. Compared to the CCD scanner, the CIS scanner has only about one tenth of the optical path, hence 10 times light illumination, and allows at least 10 times faster scanning speed. In order to project three-line images for each line scan, the CIS module requires a special self-focus lens array. A high performance tri-linear sensor chip is very difficult to design due to the limited and restricted optical space between each photo-sensing array required by the lens array. High quality images cannot be obtained with the tri-linear phototransistor-type CIS sensor chip as described in the U.S. patent, “CMOS Photodetectors with Wide Range Operating Region” by Pao-Jung Chen, U.S. patent, (U.S. Pat. No. 5,869,857), Feb. 1999.

The other type of CIS module is the three-color LED CIS module, which uses a three-color LED light guide as the module light source and a single linear image-sensing array as the module sensor chip. This color CIS module was presented in the data sheet of “Color Contact Image Sensor CXA-30216C-000” of Canon Components Inc., June 1996. During each line of the scanning, the LED light source pulses the three RGB LED diodes sequentially, and the sensing array reads three times sequentially for R, G, and B color information to reproduce the color image of each scan. The scanning speed of this type of CIS module is very slow because each line requires three readings, and the LED diode's light illumination is not strong enough for short integration time or high speed scanning. Low cost, high image quality, but low speed, 1200 dpi resolution, three-color LED CIS scanners are currently available in the market.

A higher speed scanner would be very desirable for the market.

### SUMMARY OF THE INVENTION

A single-linear three-color CIS image sensing chip is invented by forming the red, green, and blue (RGB) color filters, using photo-lithography technology, on each photo-detecting element of the sensor chip, and outputting the photo-detecting signals with a single-channel output amplifier or three-channel (RGB) output amplifier as illustrated in FIG. 5 and FIG. 6 respectively.

By coating the RGB filters sequentially, in the order of RGBRGB . . . on each photo-detecting element of the high performance single-linear image sensing array of CIS sensor chips, and incorporating the fluorescent lamp as the light source, a high speed, high performance, and cost-effective color CIS scanner can be obtained. A linear CIS array with 1200 dpi monochrome resolutions will produce a linear color CIS array with 400 dpi resolutions.

### BRIEF DESCRIPTION OF THE DRAWINGS

FIG. 1 illustrates the block diagram of a tri-linear phototransistor color CIS sensor chip.

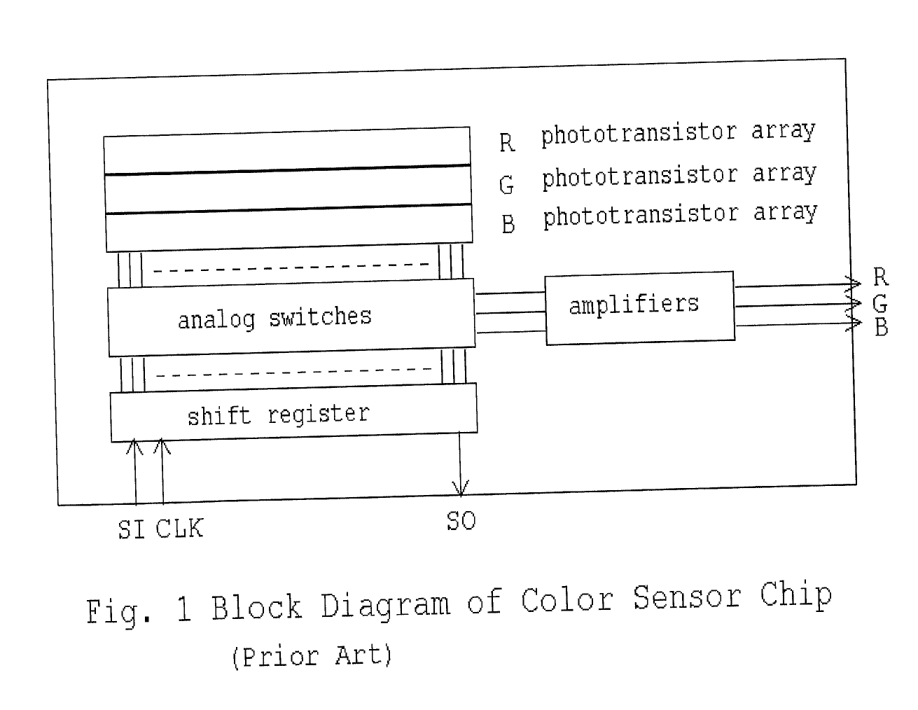

FIG. 2 illustrates the pixel arrangement of the photo-detecting cells of the tri-linear phototransistor-type color CIS sensor chip.

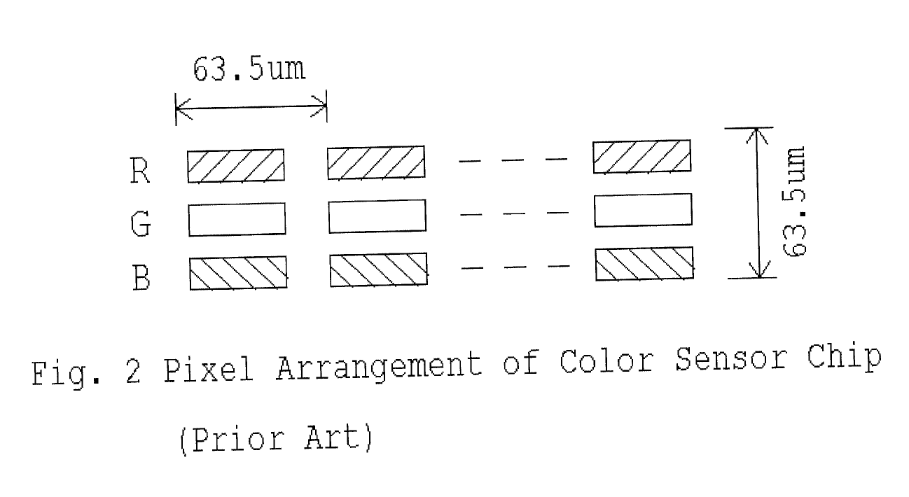

FIG. 3 illustrates the cross sectional view of the tri-linear phototransistor-type color CIS module.

FIG. 4 illustrates the cross sectional view of a three-color LED CIS module.

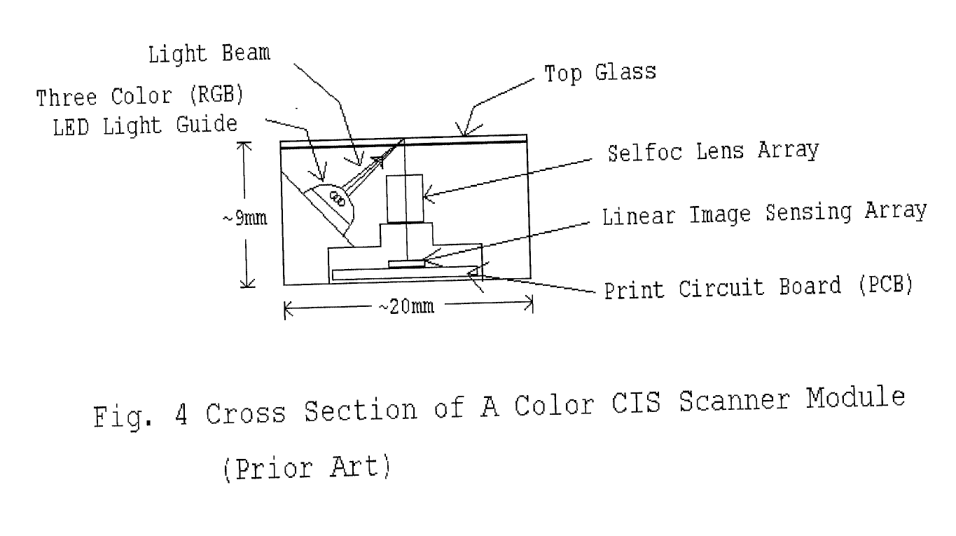

FIG. 5 illustrates the block diagram of a single-linear color CIS sensor chip with one readout channel.

FIG. 6 illustrates the block diagram of a single-linear color CIS sensor chip with three (RGB) readout channel.

FIG. 7 illustrates the block diagram of a single-linear CCD color CIS sensor chip.

### DESCRIPTION OF THE PREFERRED EMBODIMENT

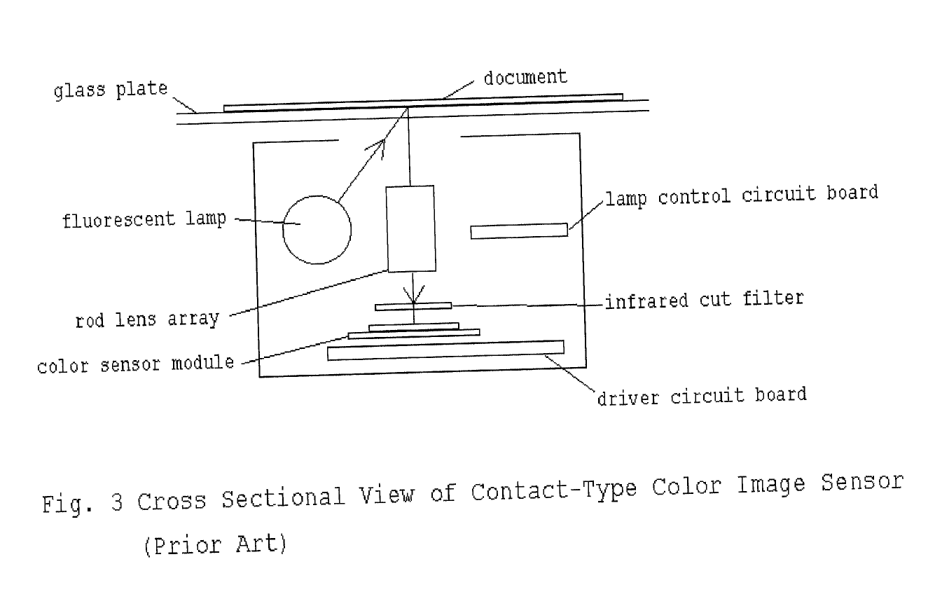

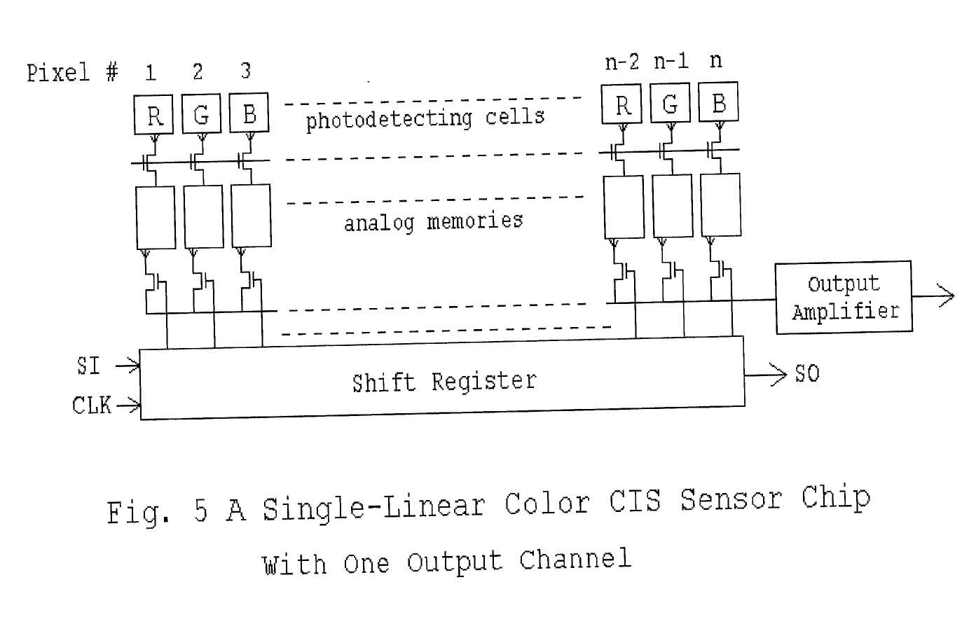

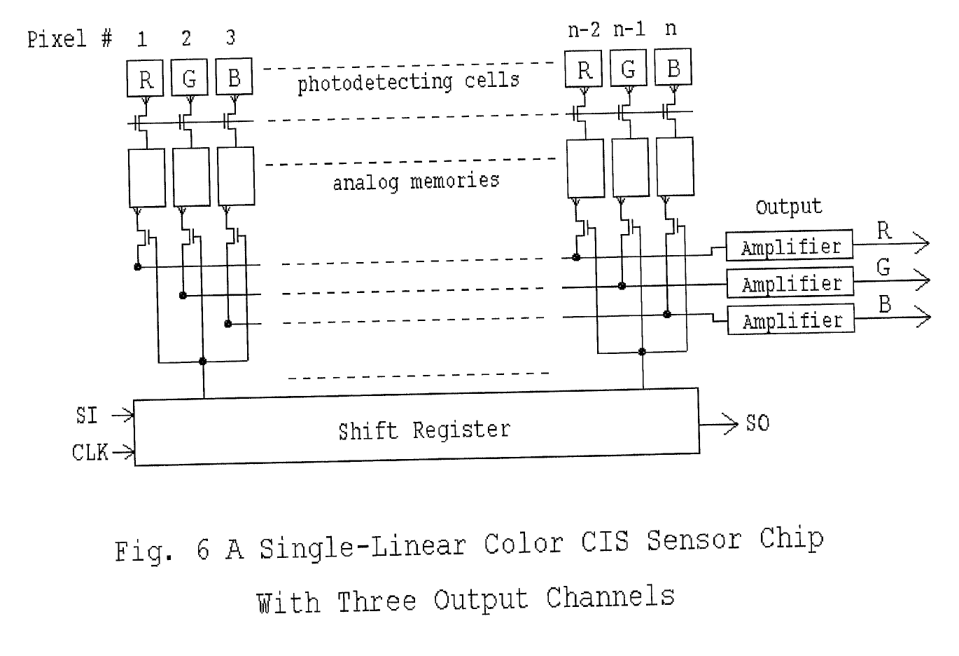

Referring to FIG. 5 of the present invention, a single-linear color CIS sensor chip is illustrated. By coating the photo-detecting cells of a linear image-sensing array sequentially with three color filters, red, green and blue, and incorporating the fluorescent lamp as the light source, a high speed, high performance color CIS scanner module can be obtained. The cross section view of this CIS module is similar to that of the tri-linear color CIS scanner module illustrated in FIG. 3. The fluorescent lamp has at least ten times light irradiating intensity than the LED light guide. The line rate for each scan can be ten times faster than the three-color LED CIS scanner. The line rate can be even faster if three-output channel readout structure is implemented as illustrated in FIG. 6. In this configuration, the array of photo-detecting cells is grouped into an array of color-space pixels, and each color-space pixel includes three photo-detecting cells, R, G, and B. During each line scan, each output bit of the shift register activates concurrently the three readout switch transistors of the color-space pixel, and outputs the RGB signals to each respective RGB output amplifiers. Therefore, a linear array of 3N photo-detecting cells requires an N bit shift register to complete a line scan, which is three times faster than the linear array of 3N photo-detecting cells with single output channel, which requires 3N bits shift register for a line scan.

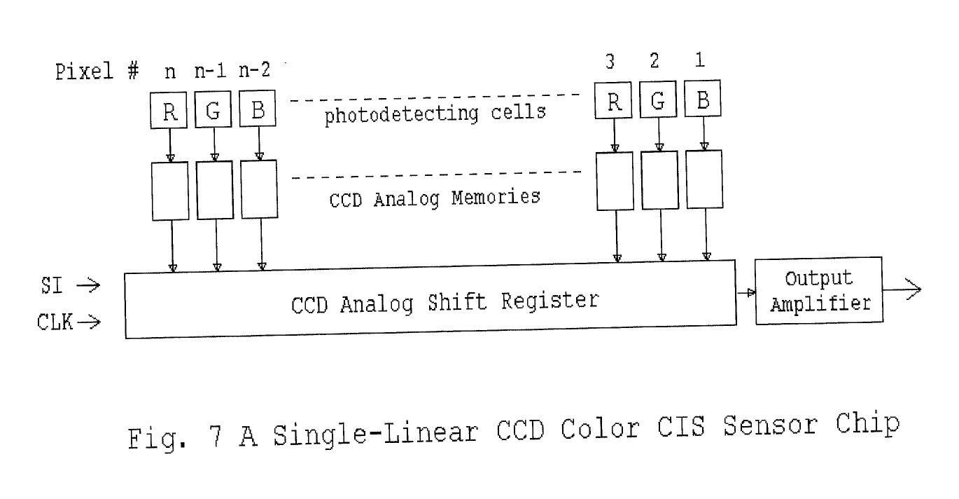

FIG. 7 illustrates a single-linear CCD color CIS sensor chip, which uses charge-coupled device (CCD) cells as analog memories and analog shift register for outputting the video signals from the photo-detecting cells.

The above disclosure is not intended as limiting. Those skilled in the art will readily observe that numerous modifications and alternations of the device may be made while retaining the substance of the invention. Accordingly, the above disclosure should be construed as limited only by the metes and bounds of the appended claims.

I claim:

1. A single-linear color CIS image sensing chip supported on a substrate comprising:
a single linear array of photo-detecting cells having the red, green and blue (RGB) color filters sequentially coated on each of said photo-detecting cells for receiving the color information of the scanned object and a read-out switch for outputting said received signal;
an array of sample-and-hold amplifiers having a terminal connected to said readout switch transistor for receiving the color signals from said photo-detecting cells and a sample-and hold read-out switch transistor for outputting said received signal;
a digital scanning shift register having a plurality of bits with each of said bits connected to a gate terminal of each of said sample-and hold readout switch transistors for sequentially reading out a video signal detected by said photo-detecting cells; and
an output amplifier readout circuit including a buffer amplifier connected to a common source terminal of said readout switch transistors of said sample-and-hold amplifiers for sequentially receiving and outputting a video signal from said photo-detecting cells.

2. The single-linear RGB color CIS image sensor of claim 1 is a CMOS photo-diode image-sensing array with one readout amplifier to output sequentially the video signals from the photo-detecting cells.

3. The single-linear RGB color CIS image sensor of claim 1 is a CMOS photo-diode image-sensing array with three readout amplifiers (R amplifier, B amplifier and G amplifier) to output concurrently and sequentially the video signals from the first three pixels to the last three pixels of the photo-detecting cells.

4. The single-linear RGB color CIS image sensor of claim 1 is a CCD image-sensing array with one readout amplifier to output sequentially the video signals from the photo-detecting cells.

5. A method of forming a single-linear RGB color CIS image sensing array comprising:
forming a single linear CIS image sensor with a single-linear array of photo-detecting cells;
coating the first color filter film, such as red filter film, starting from the first photo-detecting element and every other two up and so on until the end of the array;
coating the second color filter film, such as green filter film, starting from the second photo-detecting element and every other two up and so on until the end of the array; and
coating the third color filter film, such as blue filter film, starting from the first photo-detecting element and every other two up and so on until the end of the array;
